(19) United States
(12) Patent Application Publication
(10) Pub. No.: US 2026/0237417 A1
(43) Pub. Date: Aug. 13, 2026

(54) Refresh Latency Indication for Refresh Operations

(71) Applicant: Micron Technology, Inc., Boise, ID (US)

(72) Inventors: Yang Lu, Boise, ID (US); Gary Lynn Howe, Allen, TX (US); Kang-Yong Kim, Boise, ID (US)

(73) Assignee: Micron Technology, Inc., Boise, ID (US)

(21) Appl. No.: 19/053,347

(22) Filed: Feb. 13, 2025

(51) Int. Cl. G11C 11/406; G11C 11/4076

(52) U.S. Cl. CPC G11C 11/40615; G11C 11/40622; G11C 11/4076

(57) ABSTRACT

Apparatuses and techniques for implementing refresh latency indication for refresh operations are described. A memory system may separate memory dies into different ranks. Sending separate refresh commands to each rank congests the command bus. Sending a common refresh command to multiple ranks, on the other hand, causes a large current spike as many dies initiate the refresh operation at the same time. To efficiently prevent the large current spike and thereby lower the costs of a power delivery network, different dies can delay initiation of the refresh commands by different amounts. To do so, a host device can program different dies with different refresh latency indications, which determine lengths of each delay period before starting the refresh operation. The dies can also operate based on an enablement indication that enables the refresh latency mechanism. Staggering the start times of refresh operations can also control current spikes without regard to ranks.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and nonvolatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses and techniques for implementing refresh latency indication for refresh operations are described with reference to the following drawings. The same numbers are used throughout the drawings to reference like features and components:

FIG. 1 illustrates example apparatuses that can implement aspects of refresh latency indication for refresh operations;

FIG. 2 illustrates an example computing system that can implement aspects of refresh latency indication for refresh operations with respect to a memory device;

FIG. 3 illustrates an example memory device that includes multiple ranks in which aspects of refresh latency indication for refresh operations may be implemented;

FIG. 4 depicts a first timing diagram and a second timing diagram that illustrate example refresh timing schemes in which a memory device does not stagger refresh operations and in which a memory device does stagger refresh operations using refresh latency indications, respectively;

FIG. 5 illustrates a schematic diagram of example communication schemes between a host device and a memory device for refresh latency indication for refresh operations;

FIG. 6 depicts timing diagrams to illustrate examples of how refresh-timing restriction periods can be delayed with refresh latency indication for refresh operations;

FIG. 7 depicts timing diagrams to illustrate example implementations for a self-refresh mode in conjunction with refresh latency indication for refresh operations;

FIG. 8 is a flow chart that illustrates example processes for overriding an enabled refresh latency indication with respect to refresh operations;

FIG. 9 illustrates example methods for implementing aspects of refresh latency indication for refresh operations with respect to a host device; and

FIG. 10 illustrates example methods for implementing aspects of refresh latency indication for refresh operations with respect to a memory device.

### DETAILED DESCRIPTION

### Overview

Computing devices provide various services for users of mobile devices and server devices. Some computing devices include a host device, which may include a memory controller, and a memory device for storing information. For some applications, such as portable electronic devices that operate on battery power and data centers that employ thousands of memory devices, reducing power usage by memory devices can provide appreciable improvements in energy efficiency. These applications may also benefit from increasing memory performance, such as by reducing congestion on a memory bus. Some implementations that are described herein can provide one or both advantages for a memory device or system, including for those using low-power types of memory.

For example, double data rate synchronous dynamic random-access memory (DDR SDRAM), including low-power DDR (LPDDR) SDRAM, is a volatile memory. Volatile memory loses stored information if the power to the memory is not maintained. The memory cells of DRAM devices are typically made using pairs of capacitors and transistors. Information is stored using charge levels that are applied to the capacitors. This charge, however, gradually leaks from the memory cells, so the data will eventually be lost if the capacitor is not recharged. Consequently, to maintain an appropriate charge that reflects the stored data, the memory cells are periodically refreshed by restoring the correct charge level.

The rate of charge leakage from each capacitor is generally known or can be predicted. Based on this rate, the charge of each capacitor in the memory device can be repeatedly refreshed (e.g., periodically refreshed) sufficiently frequently to counteract this rate of charge loss at the capacitors. Generally, each memory cell in a volatile memory is refreshed within a DRAM retention time (e.g., approximately 64 milliseconds (ms)) to maintain the integrity of stored data. To perform a refresh operation, logic of the memory reads data from a memory cell corresponding to a refresh address into a temporary storage buffer (e.g., a sense amp) and writes the data back to the memory cell with the proper “full” charge. A refresh address can include a memory cell address, a row address, a bank address, and the like.

Refresh operations can be controlled in at least two ways. First, refresh operations can be initiated, controlled, or timed by a host device that is located external to the memory device. For instance, a memory controller can issue an auto-refresh command to a memory device. Second, refresh operations can be initiated, controlled, timed or otherwise performed internal to the memory device using a self-refresh operation. In an auto-refresh mode, the memory controller may issue a refresh command (e.g., an auto-refresh command) that corresponds to or includes one all-bank refresh (ABR) command or multiple per-bank refresh (PBR) commands, the quantity of which depends on the bank configuration. The memory controller can issue the refresh command at a frequency (e.g., at an average refresh interval (tREFI)) that is sufficient to refresh each memory cell within the DRAM retention time.

When a computing system or at least a memory subsystem is in a power-saving mode, the memory device can perform self-refresh operations at a similar rate or frequency as part of operating in a self-refresh mode. In the self-refresh mode, the memory device can control the timing and operations for refreshing rows of a DRAM array. The host device can therefore cease planning for, orchestrating, and communicating about memory refresh operations if the memory device is operating in a self-refresh mode.

In some computing devices, memory devices include multiple memory dies that are organized by memory rank or “rank.” Each memory die that is part of a given rank is coupled to a same chip select (CS) line. Thus, in some architectures, these memory dies receive the same command and addresses responsive to assertion of the common chip select line. Separating memory dies into ranks provides several benefits. First, the multiple memory ranks enable a memory module to provide a higher storage capacity. For example, a dual rank or quad rank memory module can store more data than a single rank (or non-ranked) memory module. Second, the higher storage capacity offered by a memory module can lower the cost per gigabyte. Third, some memory controllers are capable of increasing memory-access bandwidth with multi-ranked memory systems if the code under execution produces a favorable address pattern.

When a computing device includes a memory device with DRAM that is organized into multiple ranks, the host device is responsible for controlling the refreshing of the DRAM while interoperating with the multiple ranks. In one approach, the host device can transmit individual refresh commands separately to each rank by asserting the respective chip select line for each rank. As the quantity of ranks increases, however, this approach causes increasing traffic congestion on the command and address bus. The traffic congestion can impede memory accesses and reduce the effective memory bandwidth.

In another approach, the host device can transmit a single refresh command to multiple ranks. To do so, the host device “simultaneously” asserts multiple chip-select lines for respective ones of the multiple ranks in conjunction with the transmission of the refresh command. With this approach, the quantity of refresh commands can be halved in a dual-rank memory system and reduced by approximately 75% in a quad-rank memory system. Unfortunately, this approach can create a problem with current draw. This multi-rank approach can cause multiple dies in each of multiple ranks to initiate a refresh operation substantially simultaneously. The multiple concurrent refresh operations combine respective current spikes to generate a large current spike. To accommodate such a large combined current spike, the power delivery network would need to be stronger and consequently more expensive and larger.

In contrast with the large combined current spike described above, this document describes devices and techniques that cause an appreciably smaller maximum current spike. The smaller maximum current spike enables a less costly power delivery network to be employed. In example implementations, to reduce the size of the maximum current spike, the timing of the refresh operations is staggered across different memory dies. For instance, each memory die across a memory device can start refreshing DRAM at a different time. Alternatively, each memory die within a given rank can start refreshing DRAM at a different time, but one memory die in each rank can start a refresh operation at the same time. Thus, with two ranks and four memory dies per rank, four sets of refresh operations would start at four different times, and each set would entail two “simultaneous” refresh operations. As another example, each memory die within a given rank can start refreshing DRAM at the same time, but the memory dies in different ranks can start refresh operations at different times. Thus, for this example with two ranks and four memory dies per rank, two sets of refresh operations would start at two different times, and each set would entail four “simultaneous” refresh operations within each rank. With any of these staggered refresh scenarios, the maximum current spike is less than if all dies were to begin refresh operations at the same time.

In example implementations, a memory device includes at least one memory storage unit that stores a refresh latency indication. The host device can program the refresh latency indication using, for example, a program-indication command. The program-indication command can be realized with, for example, a mode register write (MRW) command, a fuse-blowing command in a test mode, and so forth. For programing fuses, the host device may be or may function as a testing device (e.g., automatic/automated testing equipment (ATE)). Thus, the at least one memory storage unit can be realized as a mode register, at least one fuse or set of fuses, and so forth. Each respective die of multiple dies can store a respective refresh latency indication of multiple refresh latency indications, at least some of which have a different value. The at least one memory storage unit can also store an enablement indication that activates or deactivates a refresh latency mechanism, or an implementation of the refresh operation delay based on the refresh latency indication, for the die of the memory device.

In example operations, a host device transmits to a memory device a command to perform a refresh operation. The memory device receives the refresh command and implements a delay period relative to the refresh command and based on the refresh latency indication. After the delay period, the memory device performs the refresh operation on at least one memory array responsive to the refresh command. Meanwhile, the host device can access parts of the memory device that are not performing a refresh operation using information about how (e.g., when and where) the refresh operations are being delayed with regard to at least one restricted-access period.

In other example implementations, a refresh command can include a latency override indicator. Occasionally, a host device may only have an available time frame that is sufficient to refresh a single rank. In at least some of such cases, instituting a delay period before a refresh operation is performed may be harmful because the restriction against accessing the single rank occurs later than is necessary without reducing a maximum current spike across multiple ranks. To overcome this potential harm, the host device can include an affirmative value for the latency override indicator. In response to the affirmative value of the latency override indicator, the memory device starts the refresh operation without implementing a delay period based on the refresh latency indication, even if the enablement indication for employing the refresh latency indication is also affirmative.

In some cases, a refresh latency indication or a corresponding enablement indication may be programmed or set separately for different types of refresh operations. Hence, there may be one setting for auto-refresh operations and another setting for self-refresh operations for the refresh latency indication or the corresponding enablement indication. Further, in accordance with a permitted herein, but optional, interpretation of the word “or” as a “disjunctive or,” the refresh latency indication and the corresponding enablement indication may be set separately for different types of refresh operations.

In these manners, a host device can efficiently issue commands to perform refresh operations to a memory device having multiple memory ranks. The host device can transmit the same refresh command to multiple ranks of memory devices without overloading a power delivery network with a large combined current spike. The large combined current spike can be averted by staggering refresh operations over time based on a refresh latency indication stored at each memory die. The staggering of the start times for refresh operations can also control a maximum current-spike magnitude without regard to the memory ranks of a memory device and for memory devices that do not separate memory dies by memory rank. These techniques avoid congesting a command and address bus with multiple separate refresh commands while obviating a need to strengthen a power delivery network (PDN). This promotes memory performance and saves PDN costs for the memory device or the computing device (e.g., for the motherboard or a system-wide printed circuit board (PCB)).

### Example Operating Environments

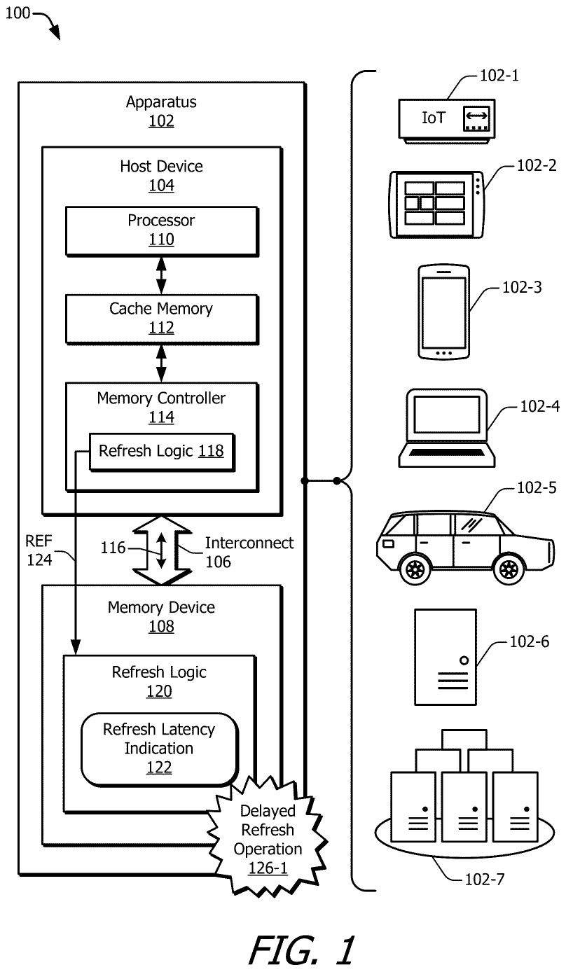

FIG. 1 illustrates, at 100 generally, an example operating environment including an apparatus 102 that can implement aspects of refresh latency indication for refresh operations. The apparatus 102 can include various types of electronic devices, including an internet-of-things (IoT) device 102-1, a tablet device 102-2, a smartphone 102-3, a notebook computer 102-4, a passenger vehicle 102-5, a server computer 102-6, or a server cluster 102-7. The server computer 102-6 or the server cluster 102-7 may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, medical device, or the electronic components of any computing device. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and at least one memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, a central processing unit (CPU), a graphics processing unit (GPU), a neural network or other artificial intelligence (AI) engine or accelerator, an application-specific integrated circuit (ASIC), a field-programmable gate array (FPGA) integrated circuit (IC), a communications processor (e.g., a modem or baseband processor), and so forth.

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests that are received from the external memory.

The host device 104 is operatively coupled, via the interconnect 106, to the memory device 108. In some examples, the memory device 108 is connected to the host device 104 via the interconnect 106 with an intervening buffer or cache. The memory device 108 may be operatively coupled to storage memory (not shown). The host device 104 can also be coupled, directly or indirectly via the interconnect 106, to the memory device 108 and the storage memory. The interconnect 106 and other interconnects (not illustrated in FIG. 1) can transfer information between two or more components of the apparatus 102. Examples of the interconnect 106 include a bus (e.g., a unidirectional or bidirectional bus), a switching fabric, or one or more wires that carry voltage-based or current-based signals. The interconnect 106 can propagate one or more communications 116, such as memory requests or memory responses, between the host device 104 and the memory device 108. For example, the host device 104 may transmit a memory request to the memory device 108 over the interconnect 106. Also, the memory device 108 may transmit a corresponding memory response to the host device 104 over the interconnect 106.

In other implementations, the interconnect 106 can be realized as a Compute Express Link® (CXL®) protocol link (CXL link). In other words, the interconnect 106 can comport with at least one CXL standard or protocol. The CXL link can provide an interface on top of the physical layer and electricals of a Peripheral Component Interconnect Express (PCIe) 5.0 physical layer, for instance. The CXL link can cause requests to and responses from the memory device 108 to be packaged as flits. In still other implementations, the interconnect 106 can be another type of link, including a PCIe 5.0 link. In this document, some terminology may draw from one or more identified standards or versions thereof, like a CXL standard or an LPDDR5 standard, for clarity. The described principles, however, are also applicable to memories and systems that comport with other memory and bus standards and other types of interconnects.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., lower than a level of the memory device 108). Memory at lower hierarchical levels may have a decreased speed but increased capacity relative to memory at higher hierarchical levels. Memory at lower hierarchical levels may also have a lower cost per bit.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory (not shown in FIG. 1). As another example, the apparatus 102 may include cache memory between the interconnect 106 and the memory device 108. Computer engineers can also include any of the described or illustrated components in distributed or shared memory systems.

This document describes with reference to FIG. 1 an example computing device or system architecture having at least one host device 104 coupled to a memory device 108. Computer engineers may implement the host device 104 and the various memories in multiple manners. In some cases, the host device 104 and the memory device 108 may be realized with separate packages that can be disposed on, or physically supported by, a printed circuit board (e.g., a rigid or flexible motherboard). The host device 104 and the memory device 108 may alternatively be integrated together on an integrated circuit or fabricated on separate integrated circuits and packaged together. The memory device 108 may also be coupled to multiple host devices 104 via one or more interconnects 106 and may respond to memory requests from two or more host devices 104. In such cases, each host device 104 may include a respective memory controller 114, or the multiple host devices 104 may share a memory controller 114.

Two or more memory components (e.g., modules, packages, dies, bank groups, or banks) can share the electrical paths or couplings of the interconnect 106. In some cases, the interconnect 106 can include at least one command-and-address bus (CA bus) and at least one data bus (DQ bus). The command-and-address bus can transmit addresses and commands from the memory controller 114 of the host device 104 to the memory device 108, and this bus may exclude propagation of data. The data bus can propagate data bidirectionally between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM). Other examples of realizations for at least the memory device 108 include computational storage apparatuses, such as Computational Storage Devices (CSXs), Computational Storage Processors (CSPs), Computational Storage Drives (CSDs), and Computational Storage Arrays (CSAs). The memory device 108 may also include or be realized as processor-in-memory (PIM).

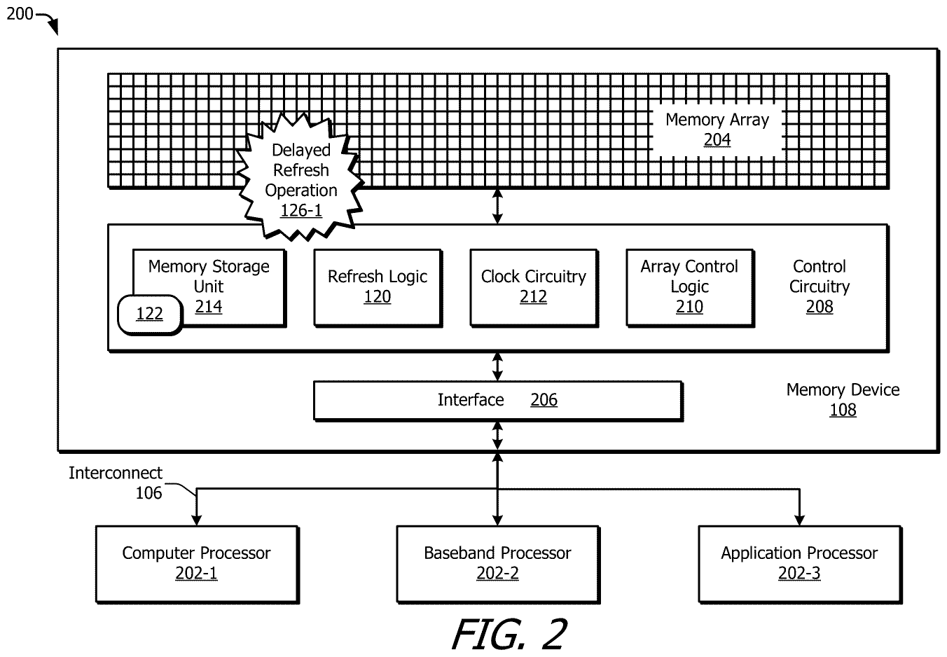

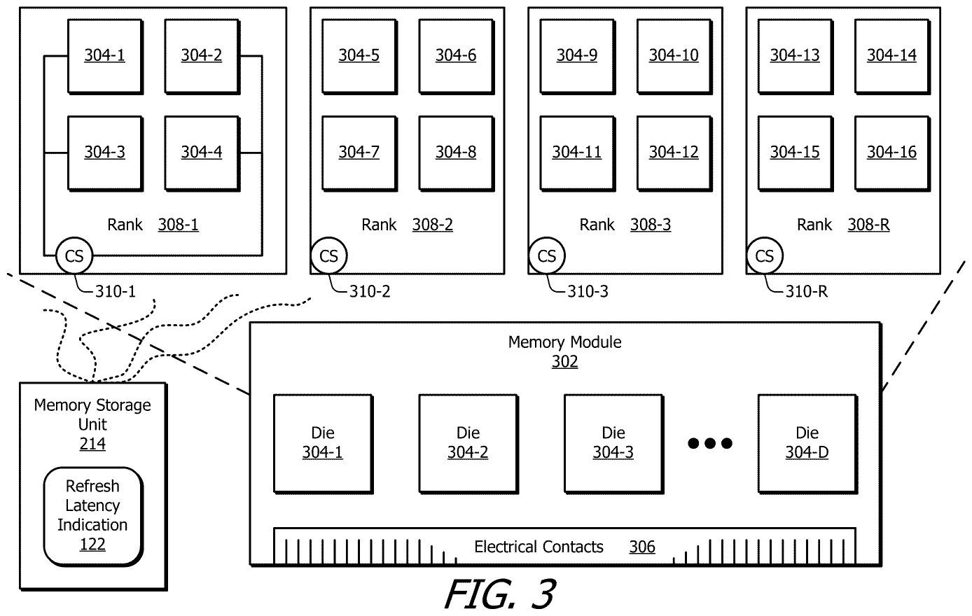

The memory device 108 can form at least part of the main memory of the apparatus 102. The memory device 108 may, however, form at least part of a cache memory, a storage memory, or a system-on-chip of the apparatus 102. The memory device 108 can include at least one memory array (e.g., as shown in FIG. 2), at least one memory die (e.g., as shown in FIG. 3), and at least one instance of refresh logic 120. The host device 104 can include at least one instance of refresh logic 118. For instance, the memory controller 114 of the host device 104 can include the refresh logic 118. The refresh logic 118 individually, the refresh logic 120 individually, or the refresh logic 118 in combination with the refresh logic 120 can realize or perform one or more implementations for refresh latency indication for refresh operations as described herein.

In example implementations, a refresh latency indication 122 enables a host device 104 to specify how long a memory device 108 delays before performing a refresh operation in response to a refresh command 124 (REF 124). Thus, the refresh logic 118 of the host device 104 can program an appropriate refresh latency indication 122 at the refresh logic 120 of the memory device 108. To do so, the host device 104 can transmit a program-indication command to establish a value for the refresh latency indication 122 prior to sending commands for refresh operations. The refresh latency indication 122 can comprise a value that the refresh logic 120 uses to compute or otherwise implement a delay period as described herein.

In example operations, the host device 104 transmits to the memory device 108 a refresh command 124. The memory device 108 receives the refresh command 124 and implements a delay period relative to the refresh command 124 and based on the refresh latency indication 122, which indication can already be stored at the memory device 108. After the delay period, the memory device 108 performs a delayed refresh operation 126-1 on at least one memory array responsive to the refresh command 124. Meanwhile, the host device 104 can access other parts of the memory device 108 that are not performing a refresh operation using information about where and when the refresh operations are being delayed, which results in a determinable shifting of restricted-access periods.

In some cases, the refresh logic 118 of the host device 104 can perform at least a portion of the functionality for refresh latency indication for refresh operations as described herein. Similarly, the refresh logic 120 of the memory device 108 can perform at least a portion of the functionality for refresh latency indication for refresh operations as described herein. In example implementations, the refresh logic 118 or the refresh logic 120 can be realized using circuitry, such as digital circuitry. Thus, the refresh logic 118 and the refresh logic 120, either separately or in combination with each other, can cause the memory device 108 to selectively perform a delayed refresh operation 126-1. One or more delayed refresh operations 126-1 enable current spikes on a per-die basis to be separated in time with respect to other dies such that all dies do not contribute to a combined current spike at the same time. In these manners, the refresh logic 118 or the refresh logic 120 can reduce bus traffic by transmitting a single refresh command to multiple memory ranks without generating a large combined current spike that would necessitate a more-costly power delivery network.

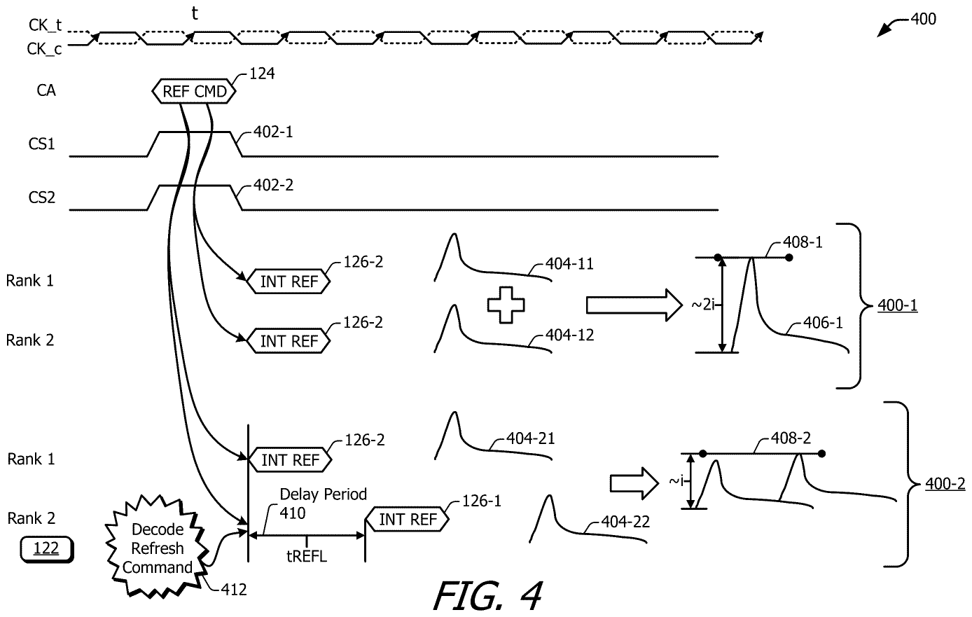

With reference to the two timing diagrams of FIG. 4, this document describes an example of how implementing delayed refresh operations 126-1 can stagger current spikes and therefore reduce a maximum current spike caused by initiating refresh operations across multiple dies and memory ranks. Prior to that description, examples are described below with reference to FIG. 3 of memory architectures for a memory device 108 in which memory dies are separated into different memory ranks. In some cases, delayed refresh operations 126-1 may be performed with regard to the memory rank of which a die is part. Next, however, this document describes examples of the memory device 108 with reference to FIG. 2.

FIG. 2 illustrates an example computing system 200 that can implement aspects of refresh latency indication for refresh operations with respect to a memory device 108. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) that is operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. The control circuitry 208 may manage traffic on a bus that is separate from the interconnect 106, such as an internal bus of the memory device 108.

The control circuitry 208 can include various components that the memory device 108 can use to perform various operations. These operations can include communicating with other devices, managing memory performance, performing refresh operations (e.g., self-refresh operations or auto-refresh operations for DRAM), and performing memory read or write operations. For example, the control circuitry 208 can include at least one instance of array control logic 210, clock circuitry 212, at least one instance of refresh logic 120, and at least one memory storage unit 214. The array control logic 210 can include circuitry that provides command decoding, address decoding, input/output functions, amplification circuitry, power supply management, power control modes, sense amplifying for data retrieval operations, write driving for data storage operations, and other functions.

The clock circuitry 212 can synchronize various memory components with one or more external clock signals provided over the interconnect 106, including a command-and-address clock or a data clock. The clock circuitry 212 can also or instead use an internal clock signal to synchronize memory components, and the clock circuitry 212 may provide timer functionality, such as for self-refresh operations. The refresh logic 120 can perform refresh operations on the memory array 204 (e.g., if the memory array 204 includes DRAM cells) in a self-refresh mode or an auto-refresh mode. The refresh logic 120 can also perform at least part of the memory-device-side operations for using a refresh latency indication to delay refresh operations as described herein.

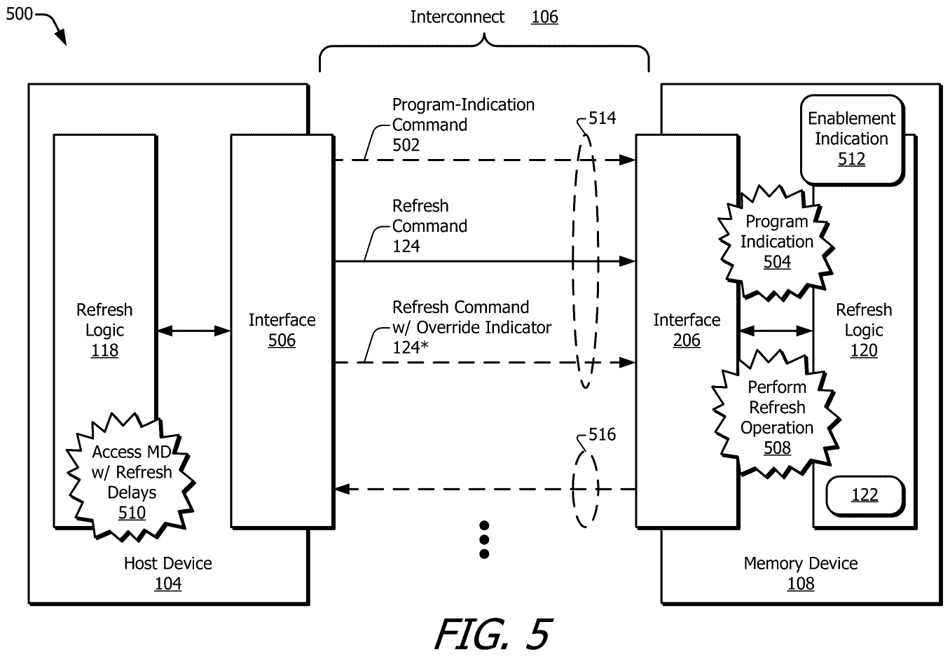

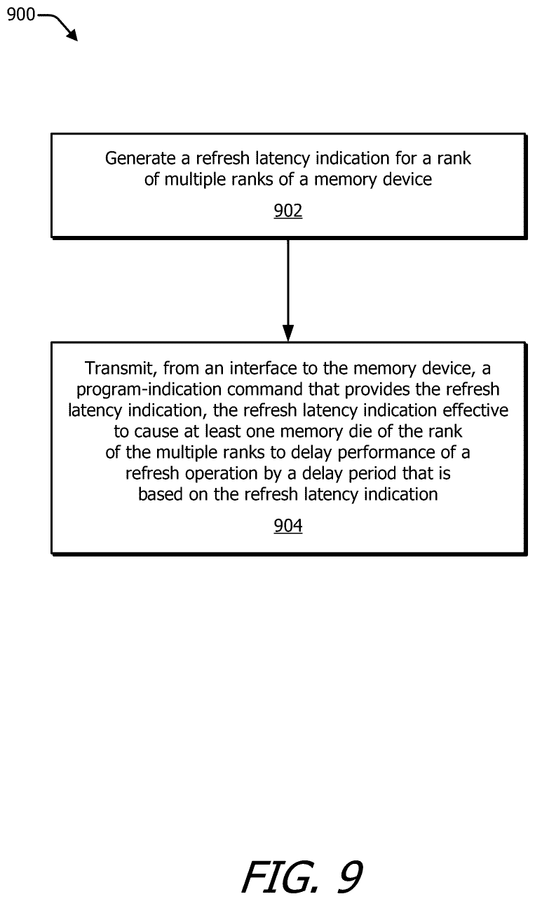

In example implementations, the control circuitry 208 can include at least one memory storage unit 214. The memory storage unit 214 can be realized as at least one register (e.g., a mode register), at least one fuse (e.g., a set of fuses that represent a value), and so forth. The memory storage unit 214 can store a refresh latency indication 122, an enablement indication for delaying refresh operations, and so forth. An enablement indication 512 for enabling/disabling a refresh latency mechanism is described below with reference to FIGS. 5, 7, and 8. Based on the refresh latency indication 122, the refresh logic 120 can perform a delayed refresh operation 126-1 in response to receipt of a refresh command. Programming the memory storage unit 214 to include a refresh latency indication 122 is described herein with reference to FIGS. 5 and 9. Generally, although not explicitly shown in FIG. 2, the control circuitry 208 may include one or more mode registers to facilitate control by and/or communication with a processor 202. Thus, by way of example, at least one refresh latency indication 122 can be stored in one or more mode registers.

The interface 206 can couple the control circuitry 208 or the memory array 204 directly or indirectly to the interconnect 106. In some implementations, the array control logic 210, the clock circuitry 212, and the refresh logic 120 can be part of a single component (e.g., the control circuitry 208). In other implementations, one or more of the array control logic 210, the clock circuitry 212, or the refresh logic 120 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and a processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus. Also, as discussed above with respect to FIG. 1, the interconnect 106 can include a CXL link or comport with at least one CXL standard. The CXL link can provide an interface or overlay on top of the physical layer and electricals of, e.g., a PCIe 5.0 physical layer.

In some aspects, the memory device 108 may be a “separate” component relative to the host device 104 (of FIG. 1) or any of the processors 202. The separate components can include a printed circuit board (PCB), memory card, memory stick, or memory module (e.g., a single in-line memory module (SIMM), dual in-line memory module (DIMM), or CXL memory module). Separate physical components may be located together within the same housing of an electronic device or may be distributed over a server rack, a data center, and so forth. Alternatively, the memory device 108 may be integrated with other physical components, including the host device 104 or the processor 202, by being combined together on a printed circuit board, in a single package, or in a system-on-chip (SoC).

As shown in FIG. 2, the one or more processors 202 may include a computer processor 202-1, a baseband processor 202-2, and/or an application processor 202-3 that are coupled to the memory device 108 through the interconnect 106. The processors 202 may include or form a part of a central processing unit (CPU), graphics processing unit (GPU), system-on-chip (SoC), application-specific integrated circuit (ASIC), or field-programmable gate array (FPGA). In some cases, a single processor can comprise multiple processing resources or cores, each dedicated to different functions (e.g., modem management, applications, graphics, security, artificial intelligence (AI), or central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). Further, the processor 202 may be realized as one that can communicate over a CXL-compatible interconnect. Accordingly, a respective processor 202 can include or be associated with a respective link controller. Alternatively, two or more processors 202 may access the memory device 108 using a shared link controller. In some of such cases, the memory device 108 may be implemented as a CXL-compatible memory device (e.g., as a CXL Type 3 memory expander), or another memory device that is compatible with a CXL protocol may also or instead be coupled to the interconnect 106.

FIG. 3 illustrates an example memory device 108 in which aspects of refresh latency indication for refresh operations can be implemented. The memory device 108 includes a memory module 302, which can include multiple dies 304. As illustrated, the memory module 302 includes a first die 304-1, a second die 304-2, a third die 304-3, and a Dth die 304-D, with D representing a positive integer. One or more of the multiple dies 304-1 to 304-D can be part of a rank 308. Memory ranks are described below. The memory module 302 can be, for example, a SIMM or a DIMM. As another example, the memory module 302 can interface with other components via a bus interconnect (e.g., a Peripheral Component Interconnect Express (PCIe®) bus) or can be another type of memory module, such as a CXL memory module. The memory device 108 illustrated in FIGS. 1 and 2 can correspond, for example, to any one or more of the multiple dies (or dice) 304-1 through 304-D or to a memory module 302 having two or more dies 304. As shown, the memory module 302 can include one or more electrical contacts 306 (e.g., pins) to interface the memory module 302 to other components.

The memory module 302 can be implemented in various manners. For example, the memory module 302 may include a printed circuit board, and the multiple dies 304-1 through 304-D may be mounted or otherwise attached to the printed circuit board. The dies 304 (e.g., memory dies 304) may be arranged in a line in one dimension or along two or more dimensions (e.g., forming a grid or array of dies). The dies 304 may have a similar size to each other or may have different sizes. Each die 304 may be similar to another die 304 or different in size, shape, data capacity, control circuitries, or functionality. The dies 304 may also be positioned on a single side or on multiple sides of the memory module 302 or positioned within a memory module housing. In some cases, the memory module 302 may be part of a CXL memory system or module as described below.

In example implementations, the memory module 302 includes a first rank 308-1, a second rank 308-2, a third rank 308-3, and an Rth rank 304-R, with R representing a positive integer. In a single-rank module, R represents one. In a multi-rank module, R represents an integer of two or more. For example, in a dual-rank system R represents two, and in a quad-rank system R represents four. A memory module can have, however, a different quantity of ranks, such as 8, 16, or more. In some cases, each rank 308 shares or has a common chip select 310 (CS 310). Hence, a quantity of chip selects 310 may be equal to a quantity of ranks 308. With the illustrated example of four ranks 308-1 to 308-R (where R is four), there are four chip selects 310-1 to 310-R.

In the illustrated example, the memory module 302 includes 16 memory dies 304-1, 304-2, 304-3, . . . , 304-14, 304-15, and 304-16 (D represents 16 here) and four memory ranks 308-1, 308-2, 308-3, and 308-R (R represents four here). In cases in which each rank 308 has an equal quantity of memory dies 304, there are four memory dies 304 per rank 308 with 16 dies distributed across 4 memory ranks. Thus, the first rank 308-1 includes four memory dies: a first die 304-1, a second die 304-2, a third die 304-3, and a fourth die 304-4. The ranks and dies may, however, be arranged or distributed differently.

Each chip select 310 may represent a chip select line, a chip select pin, a chip select input, some combination thereof, and so forth. In example operations, a host device can jointly access (e.g., send a command or an address) to each of the memory dies 304 of a particular rank 308-x by asserting the corresponding chip select 310-x. An example of such an interconnection is depicted for the first rank 308-1. As shown, the first chip select 310-1 is coupled to each of the first die 304-1, the second die 304-2, the third die 304-3, and the fourth die 304-4. This coupling may be accomplished via a respective chip select pin (not separately indicated) of each respective die 304-1 to 304-4. Although a particular architecture and organization of the memory module 302 is depicted in FIG. 3 and described herein (including example quantities of components), this is by way of example only. A memory module 302 may have a different architecture, organization, or quantity of components, such as four memory dies per rank with two ranks in a memory module 302 or two memory dies per rank with eight ranks in a memory module 302.

Generally, a memory device such as the ones described herein can be secured to a printed circuit board (PCB), such as a rigid or flexible motherboard. The printed circuit board can include sockets for receiving at least one processor and one or more memory devices. Wiring infrastructure can be disposed on at least one layer of the printed circuit board, enabling communication between two or more components. Some printed circuit boards include multiple sockets that are each shaped as a linear slot designed to accept a dual in-line memory module (DIMM) (e.g., a memory device). These sockets can be fully occupied by dual in-line memory modules while a processor is still able to utilize additional memory. In such situations, the system is capable of greater performance if additional memory is available to the processor.

Printed circuit boards may also include at least one peripheral component interconnect express (PCIe®) slot. A PCIe slot is designed to provide a common interface for various types of components that may be coupled to a PCB. The PCIe protocol can provide higher rates of data transfer, smaller footprints, or both to the PCB compared to some other standards. Accordingly, certain PCBs enable a processor to access a memory device that is connected to the PCB via a PCIe slot.

In some implementations, accessing a memory solely using a PCIe protocol may not offer a desired functionality or reliability. In such implementations, another protocol may be layered on top of the PCIe protocol. As an example, one higher-level protocol is the Compute Express Link™ (CXL™) protocol, such as versions 1.x, 2.x, 3.x, and future versions. The CXL protocol can be implemented over a physical layer that is governed by, for example, the PCIe protocol. The CXL protocol can provide a memory-coherent interface capable of high-bandwidth or low-latency data transfers or data transfers with both conditions.

The CXL protocol addresses some of the limitations of PCIe links by providing an interface that leverages, for example, the PCIe 5.0 physical layer while providing lower-latency paths for memory access and coherent caching between processors and memory devices. The CXL protocol can offer high-bandwidth, low-latency connectivity between a host device (e.g., at least one processor, one or more central processing units (CPUs), at least one system-on-a-chip (SoC)) and memory devices (e.g., dual in-line memory modules, accelerators, memory expanders). The CXL protocol also addresses growing high-performance computational workloads by supporting diverse processing and memory systems with potential applications in AI, machine learning (ML), advanced driver assistance systems (ADAS), and other high-performance computing environments. Thus, in addition to or instead of a single in-line memory module (SIMM) or a dual in-line memory module (DIMM), a memory device 108 and/or a memory module 302 can also include or be realized as a CXL memory module.

With continuing reference to FIG. 3, a memory storage unit 214 is depicted. The memory storage unit 214 stores at least one refresh latency indication 122. In some cases, each rank 308 includes at least one memory storage unit 214 to enable per-rank control of refresh latency indications for refresh operations. Such a per-rank memory storage unit 214 can be part of a die 304 of each memory rank or mounted on a PCB separately from the dies of each memory rank. In other cases, each respective die 304 includes a respective memory storage unit 214 to enable per-die control of refresh latency indications for refresh operations.

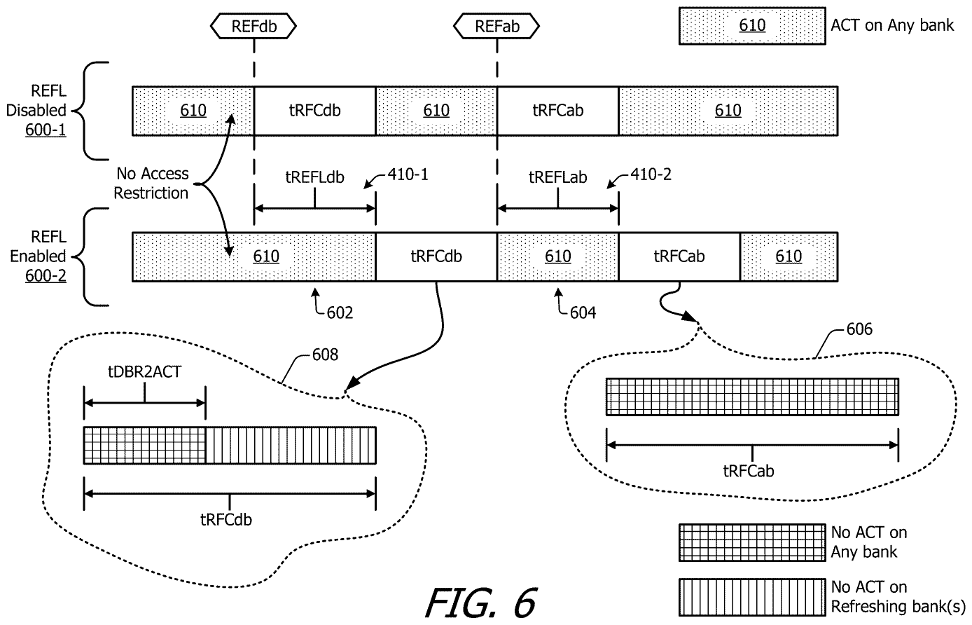

In some implementations, each refresh latency indication 122 can be programmed independently or differently. Thus, each rank 308 or each die 304 may store a different refresh latency indication 122 as compared to other ranks or dies, respectively. In other implementations, two or more refresh latency indications 122 can have different values from each other while at least two refresh latent indications 122 have a same value. For example, all dies 304 within each rank 308 can have the same refresh latency indication 122 while dies 304 in other ranks 308 have different values for their respective refresh latency indications 122. Although not necessary for all implementations, this assignment of refresh-latency-indication values staggers current spikes to reduce a maximum current spike and still preserves an ability to use unrestricted-access periods (which are described below with reference to FIG. 6) effectively because of the shared command-and-address bus.

As another example, half of the dies 304 in each rank 308 can have the same value, and half can have a different value. But those two values can be different from the values of dies 304 in other ranks 308. As yet another example, a respective die 304 in each rank 308 can have a same value across multiple ranks 308, but each die 304 within a given rank 308 has a different value from the other dies 304 in the given rank 308. Further, refresh latency indications 122 can be assigned to or programmed at multiple dies 304 without regard to rank 308 and in memory systems that lack ranks 308. Generally, the memory storage units 214 of dies 304 or ranks 308 can be programmed with various values for the respective refresh latency indication 122 using a program-indication command as described below with reference to FIG. 5.

### Example Techniques and Hardware

FIG. 4 depicts a first timing diagram 400-1 and a second timing diagram 400-2 that illustrate example refresh timing schemes in which a memory device does not stagger refresh operations and in which a memory device does stagger refresh operations using refresh latency indications, respectively. As shown at 400 generally, the timing diagrams 400-1 and 400-2 are illustrated in relation to the same refresh command scenario. A clock signal CK_c (CK_t) is depicted at the top of the diagram 400. Below the clock signal CK_c, a command-and-address bus CA is depicted. At time t, a host device transmits a refresh command 124 (REF CMD) on the CA bus. Two chip select (CS) lines are depicted below the CA bus. Also at the time t, the host device asserts a first chip select line CS1 at 402-1 and a second chip select line CS2 at 402-2.

The first timing diagram 400-1 corresponds to a scenario in which a memory device does not offer functionality for specifying a refresh latency indication for refresh operations or has such functionality disabled. The first rank 1 is coupled to the first chip select line CS1, and the second rank 2 is coupled to the second chip select line CS2. In response to the refresh command 124, the memory dies of the first rank 1 perform an internal refresh operation 126-2 without a delay period. In response to the refresh command 124, the memory dies of the second rank 2 also perform an undelayed internal refresh operation 126-2.

The current draws for the first timing diagram 400-1 are shown at 404-11 and 404-12. For both the first and second ranks 1 and 2, the current draw spikes at the beginning of the performance of the undelayed refresh operation 126-2. The total current across the two ranks for the first timing diagram 400-1 is shown as a first total current draw 406-1. Because the two undelayed refresh operations 126-2 start at substantially the same time in the two ranks, the current draw is additive. The maximum current spike 408-1 (of approximately 2i) is greater for the first total current draw 406-1 than for the individual current draws 404-11 and 404-12. Moreover, the current spike differential would be even greater, and the demand on the power delivery network would likewise be even greater, if the quantity of ranks were greater than two.

In contrast, the second timing diagram 400-2 corresponds to a scenario in which a memory device does have functionality for specifying a refresh latency indication for refresh operations and has such functionality enabled. Again, the first rank 1 is coupled to the first chip select line CS1, and the second rank 2 is coupled to the second chip select line CS2. The memory dies of the first rank 1 do not have a refresh latency or have a zero refresh latency value/amount. Accordingly, in response to the refresh command 124, the memory dies of the first rank 1 perform an internal refresh operation 126-2 without a delay period (an undelayed refresh operation 126-2) in the second timing diagram 400-2.

The memory dies of the second rank 2 have an enabled refresh latency with a delay period 410 that is derived from a refresh latency indication 122. At 412, the memory dies of the second rank 2 decode the refresh command 124. This command decoding initiates the elapsing of the delay period 410. The delay period 410 can also be referred to as a refresh latency time (tREFL). Thus, in response to the refresh command 124, the memory dies of the second rank 2 perform a delayed internal refresh operation 126-1 after expiration of the delay period 410.

The current draws are shown at 404-21 and 404-22. For the first rank 1, the current spikes at the beginning of the performance of the undelayed refresh operation 126-2. For the second rank 2, the current spikes at the beginning of the performance of the delayed refresh operation 126-1, which occurs after the undelayed refresh operation 126-2 by the refresh latency time (tREFL). The two current spikes are therefore separated in time. The total or joint current across the two ranks for the second timing diagram 400-2 is shown as a second total current draw 406-2.

Because the undelayed refresh operation 126-2 and the delayed refresh operation 126-1 start at different times in the two ranks, the total current draw is at least predominantly nonadditive. Consequently, the maximum current spike 408-2 (of approximately i) for the second total current draw 408-2 is about the same as, or only slightly greater than, the maximum current spike for each of the individual current draws 404-21 and 404-22. By employing a refresh latency indication 122 to create a delay period 410 and thereby perform at least one delayed refresh operation 126-1, the systems and techniques that are described herein can reduce the maximum current spike magnitude that results from commanding multiple memory dies to perform refresh operations 126 using a single refresh command 124 without increasing the cost of the power delivery network.

FIG. 5 illustrates a schematic diagram 500 of example communication schemes between a host device 104 and a memory device 108 for refresh latency indication for refresh operations. As shown, the memory device 108 includes the interface 206 and the refresh logic 120. Thus, the memory device 108 can communicate with the host device 104 via the interconnect 106 using the interface 206. The host device 104 includes an interface 506 and the refresh logic 118. The host device 104 can communicate with the memory device 108 via the interconnect 106 using the interface 506.

More specifically, the interface 506 and the interface 206 can be coupled to the interconnect 106. The interface 506 of the host device 104 may be configured to be coupled to the memory device 108 via the interconnect 106. Similarly, the interface 206 of the memory device 108 may be configured to be coupled to the host device 104 via the interconnect 106. The refresh logic 120 is coupled to the interface 206, and the refresh logic 118 is coupled to the interface 506. Thus, the refresh logic 118 and the refresh logic 120 can exchange communications with each other over the interconnect 106 using respective interfaces.

Generally, the refresh logic 118 can perform for the host device 104 functionality related to implementing delayed refresh operations at the memory device based on at least one refresh latency indication. Analogously, the refresh logic 120 can perform for the memory device 108 functionality related to implementing delayed refresh operations at the memory device based on at least one refresh latency indication. The example commands, signals, actions, communications, and other operations depicted in FIG. 5 and described below may be implemented in alternative manners in terms of sequence/order, addition, omission, modification, combination, and so forth in accordance with the circuitry or programming of a host device and/or a memory device.

In example implementations, the refresh logic 118 generates a program-indication command 502. The refresh logic 118 uses the interface 506 to transmit the program-indication command 502 to the memory device 108 over the interconnect 106. The refresh logic 120 receives the program-indication command 502 from the refresh logic 118 via the interconnect 106 using the interface 206. In response, the refresh logic 120 programs the indication at 504. For example, the refresh logic 120 can store at least one refresh latency indication 122 in a memory storage unit 214 (e.g., of FIG. 2). Thus, the refresh logic 120 may be capable of writing to registers, changing fuse settings, and so forth. Alternatively, other control circuitry 208 (e.g., of FIG. 2) can program the refresh latency indication 122 by writing to a mode register, blowing at least one fuse, and so forth.

At some time, the refresh logic 118 generates a refresh command 124. The refresh command 124 may be, for example, an auto-refresh command or a self-refresh command. The refresh logic 118 uses the interface 506 to transmit the refresh command 124 to the memory device 108 over the interconnect 106. The refresh logic 120 receives the refresh command 124 from the refresh logic 118 via the interconnect 106 using the interface 206. In response, the refresh logic 120 performs a refresh operation at 508. If the programmed refresh latency indication 122 has a non-zero time (and is enabled), the refresh logic 120 performs a delayed refresh operation 126-1 (e.g., of FIGS. 1 and 4). Otherwise, the refresh logic 120 may perform an undelayed refresh operation 126-2 (e.g., of FIG. 4). Meanwhile, the host device 104 can continue to access at 510 other portions (e.g., other memory dies or banks) of the memory device 108 that are not performing a refresh operation 126 in accordance with access restrictions (e.g., a restricted-access period or an unrestricted-access period) that are shifted due to a time period corresponding to the refresh latency indication 122. Examples of this are described below with reference to FIG. 6.

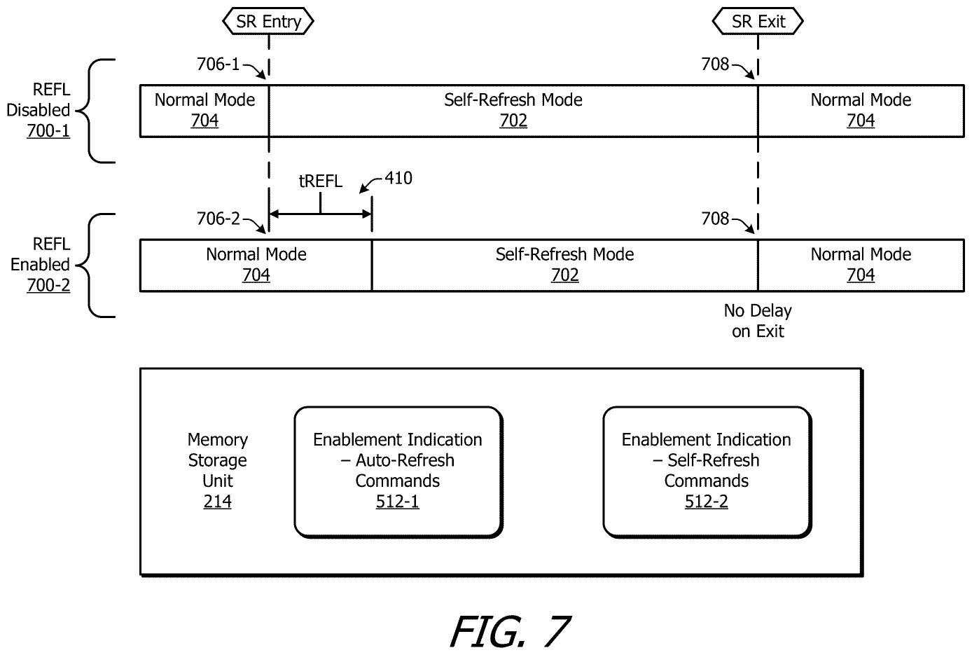

In addition to a refresh latency indication 122, implementations for delaying refresh operations in accordance with a refresh latency indication can include an enablement indication 512. The enablement indication 512 can be programmed in the affirmative (e.g., with an affirmative value) to activate use of the refresh latency indication 122 to selectively delay refresh operations 126. Alternatively, the enablement indication 512 can be programmed in the negative (e.g., with a negative value) to deactivate use of the refresh latency indication 122 to stop delaying refresh operations 126. In some cases, the enablement indication 512 can be stored in at least one memory storage unit 214 (e.g., of FIGS. 2 and 7). Further, the enablement indication 512 may be co-located with the refresh latency indication 122 in a register (e.g., in a mode register), a set of fuses, and so forth.

Two example formats for the refresh latency indication 122 and the enablement indication 512 are set forth in the following: Table 1 and Table 2. These example formats are presented in terms of a mode register (MR) implementation of a memory storage unit 214, but the formats are applicable to other implementations.

TABLE 1

| MR Bits | Parameter | Description |
|---|---|---|
| <6:0> | REFLn (122) | tREFL = REFLn * 16nCK |
| <7> | REFL Enable (512) | 0b: Disable (default) |
| | | 1b: Enable |

In Table 1, the refresh latency indication 122 (“REFLn”) comprises an integer value that uses up to seven bits of a mode register. To determine the delay period 410 (“tREFL”), the refresh logic 120 at the memory device 108 multiplies the integer value of the refresh latency indication 122 by 16 to determine the product tREFL in clock cycles. To track the delay period, the refresh logic 120 can count the quantity of clock cycles that is computed. The enablement indication 512 (“REFL Enable”) comprises a one-bit indication to disable or enable the refresh latency mechanism.

TABLE 2

| MR Bits | Parameter | Description |
|---|---|---|
| <2:0> | REFLn (122) | tREFL = REFLn * ROUNDUP(tDBR2DBR/(8*tCK)) |
| <3> | REFL Enable (512) | 0b: Disable (default) |
| | | 1b: Enable |

In Table 2, the refresh latency indication 122 (“REFLn”) comprises an integer value that uses up to three bits of a mode register. To determine the delay period 410 (“(REFL”), the refresh logic 120 at the memory device 108 multiplies the integer value of the refresh latency indication 122 by “ROUNDUP(tDBR2DBR/(8*tCK)).” The term “DBR” refers to a data bus read, and the refresh logic 120 can obtain the value of “tCK” from another mode register, such as the RL/WL setting or the tCCD_L setting. To track the delay period, the refresh logic 120 can start a timer based on the computed “tREFL” value. The enablement indication 512 (“REFL Enable”) again comprises a one-bit indication. Generally, the approach of Table 1 uses more bits of a mode register than does Table 2, but the approach of Table 1 is easier to implement because clock cycles can be counted to track the delay period 410 instead of establishing a “full” timer.

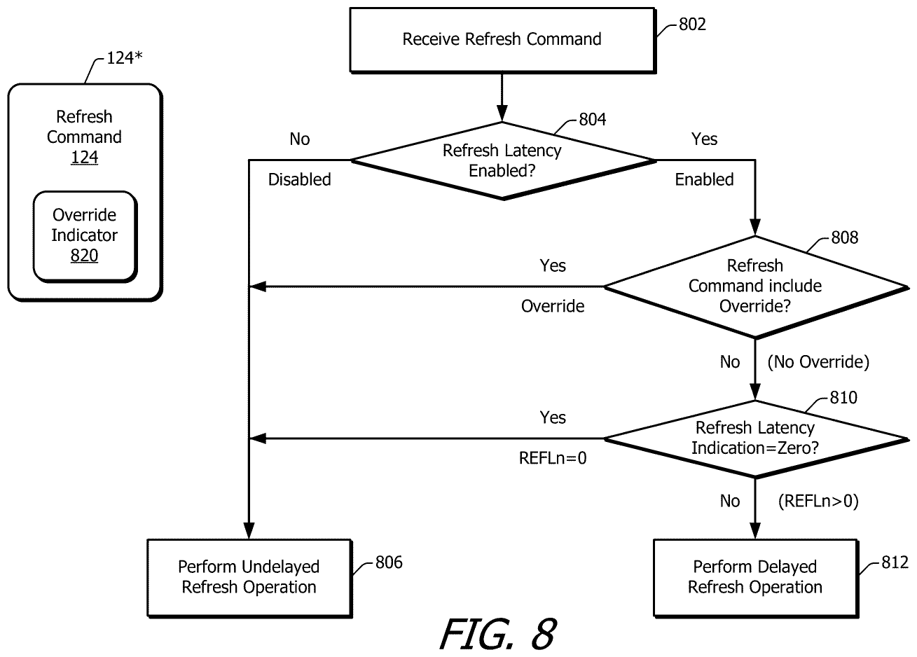

With continuing reference to FIG. 5, for memory devices or settings that include an enablement mechanism, the refresh logic 118 can use the interface 506 to transmit a refresh command with an override indicator 124* to the memory device 108 over the interconnect 106. The refresh logic 120 receives the refresh command with an override indicator 124* from the refresh logic 118 via the interconnect 106 using the interface 206. If the refresh logic 120 receives a refresh command with an override indicator 124*, the refresh logic 120 omits a delay period and instead performs an undelayed refresh operation 126-2, even if the enablement indication 512 is affirmative and signifying that the refresh-operation-delay functionality is active. Examples of this are described below with reference to FIG. 8.

As described herein, the interconnect 106 can include a command-and-address bus 514 (CA bus 514) and a data bus 516 (DQ bus 516). In at least some of such cases, the program-indication command 502, the refresh command 124, and the refresh command with override indicator 124* can be propagated over the command-and-address bus 514. For example, the refresh logic 118 can transmit the refresh command 124 over the command-and-address bus 514, and the refresh logic 120 can receive the refresh command 124 via the command-and-address bus 514. Further, a confirmation that a refresh latency indication 122 has been programmed or that a refresh operation 126 has been performed can be propagated over at least one data line of the data bus 516. For example, the refresh logic 120 can transmit confirmation of the completion of a mode register write operation over the data bus 516, and the refresh logic 118 can receive the confirmation via the data bus 516.

FIG. 6 depicts timing diagrams 600-1 and 600-2 to illustrate examples of how refresh-timing restriction periods can be delayed with refresh latency indication for refresh operations. Timing diagram 600-1 pertains to periods when refresh latency is disabled. Timing diagram 600-2 pertains to when refresh latency is enabled. For both timing diagrams, the portions with a dotted fill pattern represent that there are no restrictions on where (e.g., rank, die, or bank) the host device can access the memory device due to DRAM refreshing and are indicated as unrestricted-access periods 610. In other words, the host device can issue a command that causes an activation on any bank without considering an ongoing refresh operation. The other periods (with no fill) are restricted-access periods, which may be partially-restricted-access periods 608 or fully-restricted-access periods 606, as are described below.

For both timing diagrams, the host device issues a dual-bank refresh command (REFdb) followed by an all-bank refresh command (REFab). The dual-bank refresh command (REFdb) produces a row refresh cycle timing for the dual-bank refresh operation (tRFCdb). The all-bank refresh command (REFab) produces a row refresh cycle timing for the all-bank refresh operation (tRFCab). The temporal positioning of these two timings, however, differs between the two timing diagrams due to the delay periods 410-1 and 410-2.

For the timing diagram 600-1, the refresh latency mechanism is disabled, so there is no added latency between the decoding of the two refresh commands REFdb and REFab and the performance of the two corresponding refresh operations. Thus, the restricted-access periods and the unrestricted-access periods 610 are unshifted. In contrast, for the timing diagram 600-2, the refresh latency mechanism is enabled. Accordingly, the refresh logic of the memory device institutes a delay period 410 between the decoding of the two refresh commands REFdb and REFab and the performance of the two corresponding refresh operations. The delay period 410-1 for the dual-bank refresh operation of tREFLdb elapses before performance of the dual-bank refresh operation for tRFCdb. The delay period 410-2 for the all-bank refresh operation of tREFLab elapses before performance of the all-bank refresh operation of tRFCab. The banks that are to be refreshed are idled before the internal refresh is started.

By comparing the timing diagram 600-1 to the timing diagram 600-2, it is apparent that the length of the unrestricted access periods (with the dotted fill pattern) is the same whether the refresh latency mechanism is enabled or disabled. The timing of the unrestricted access periods, however, is shifted to occur at different temporal positions. More specifically, the unrestricted-access period 610 continues at 602 for longer in the timing diagram 600-2 after the refresh command is issued. On the other hand, the next unrestricted-access period 610 restarts later at 604. By compensating for these shifted unrestricted-access periods 610 (e.g., as extended at 602 and delayed at 604), a host device can obtain or maintain the same level of memory-accessing bandwidth whether the refresh latency mechanism is enabled or disabled.

An example of the available memory access is illustrated at 606 and 608 for fully-restricted access and partially-restricted access, respectively. At 606, for the all-bank refresh operation, no activation command (ACT) can be performed on any bank during the row refresh cycle timing for the all-bank refresh operation (tRFCab). This is represented by the horizontal and vertical crosshatch fill pattern. At 608, for the row refresh cycle timing for the dual-bank refresh operation (tRFCdb), there are two time periods. During the DBR to ACT time period (tDBR2ACT), no activation command (ACT) can be performed on any bank. In the remaining portion of the row refresh cycle timing for the dual-bank refresh operation (tRFCdb), no activation command (ACT) can be performed on the two banks being refreshed. This is represented by the vertical-line fill pattern. Meanwhile, the host device can target the other banks for memory accessing, such as the other six banks for an eight-bank memory die.

Refresh latency delays may differ based on the quantity of banks being refreshed. For example, a refresh latency delay may have one value for a dual-bank refresh command/operation and another value that is different for an all-bank refresh command/operation. This is also applicable to a per-bank refresh command (REFpb), a quad-bank refresh command (REFqb), a same-bank refresh command (REFsb), and so forth. In such cases, each relevant refresh command/operation can be associated with a respective refresh latency indication 122. Accordingly, the at least one memory storage unit 214 (e.g., of FIGS. 2 and 7) can accommodate storing multiple refresh latency indications 122. The host device can also program each of the refresh latency indications 122 using at least one program-indication command 502 (e.g., of FIG. 5).

FIG. 7 depicts timing diagrams 700-1 and 700-2 to illustrate example implementations for a self-refresh mode in conjunction with refresh latency indication for refresh operations. A refresh latency mechanism can also be employed with a self-refresh mode of the memory device. Timing diagram 700-1 pertains to periods when refresh latency is disabled. Timing diagram 700-2 pertains to when a refresh latency mechanism is enabled. For both timing diagrams, a self-refresh mode 702 is bracketed by a normal mode 704. A self-refresh entry command (SR Entry) triggers the start of the self-refresh mode 702 or the initiation of a transition from the normal mode 704 to the self-refresh mode 702. The self-refresh exit command (SR Exit) terminates the self-refresh mode 702 and restarts the normal mode 704.

In example implementations, for the timing diagram 700-1, with the refresh latency mechanism disabled, there is no refresh-latency-related delay to starting the self-refresh mode 702 after reception of the self-refresh entry command (SR Entry) as shown at 706-1. On the other hand, with the refresh latency mechanism enabled for the timing diagram 700-2, the memory device does implement a delay period 410 at 706-2 in response to the self-refresh entry command. A length of the delay period 410 is based on the refresh latency indication stored at the memory device. Thus, the memory device can use the refresh latency indication to determine the refresh latency time period (tREFL). In response to the self-refresh exit command (SR Exit), the memory device omits or does not implement a delay period whether or not the refresh latency mechanism is enabled, which is shown at 708 for both timing diagrams 700-1 and 700-2.

In some implementations, the refresh latency mechanism can be separately enabled/disabled with respect to auto-refresh commands and self-refresh commands. Thus, implementing a delay after reception of a refresh command can vary based on whether the refresh command is an auto-refresh command or a self-refresh entry command. To do so, the at least one memory storage unit 214 can store an enablement indication for auto-refresh commands 512-1 and another enablement indication for self-refresh commands 512-2. These two enablement indications 512-1 and 512-2 may be separately programmed by a host device using one or more program-indication commands 502 (e.g., of FIG. 5). The length of the latency delay may also be individually programmed for auto-refresh commands versus self-refresh commands, such as by using different refresh latency indications. Although not depicted in FIG. 6, different refresh latency indications 122 or enablement indications 512 for different bank-quantity auto-refresh commands (e.g., an all-bank refresh command and a dual-bank refresh command) can likewise be stored in the at least one memory storage unit 214.

### Example Methods

This subsection describes example methods for implementing refresh latency indication for refresh operations with reference to FIGS. 8 to 10. These descriptions may also refer to components, entities, and other aspects depicted in FIGS. 1 to 7, but by way of example only. The described methods are not necessarily limited to performance by one entity or multiple entities operating on one device. In particular, but by way of example only, the description of FIG. 5 provides multiple examples for one or more commands, responses, messages, operations, and so forth.

FIG. 8 is a flow chart 800 that illustrates example processes for overriding an enabled refresh latency indication with respect to refresh operations. The flow chart 800 includes six operations 802-812. In example implementations, a refresh command 124 can include an override indicator 820 to form a refresh command with an override indicator 124*. As described above, the inclusion of an override indicator 820 in a refresh command 124 empowers a host device to override a “standing” latency delay on a per-command basis. The override indicator 820 may comprise, for instance, a single bit of a refresh command 124 that includes multiple bits.

At 802, a memory device receives a refresh command 124. At 804, the memory device determines if the refresh latency mechanism is enabled. For example, the refresh logic 120 can inspect the enablement indication 512 stored in the memory storage unit 214. In some cases, the enablement indication 512 includes a single bit, like the examples described above with reference to Tables 1 and 2. However, an enablement indication 512 may include multiple bits, such as if there are multiple different refresh latency indications 122 for a given refresh command or for different types of refresh commands.

If the refresh latency is determined to not be enabled at 804, then the disabled branch is taken to operation 806. At 806, the memory device performs an undelayed refresh operation 126-2. Thus, the refresh logic 120 can perform, without waiting for the delay period 410, the refresh operation based on a negative value of the enablement indication 512. On the other hand, if the refresh latency is determined to be enabled at 804, then the enabled branch is taken to operation 808. At 808, the memory device determines if the refresh command 124 comprises a refresh command with an override indicator 124*. If so, then the override indicator 820 in the current refresh command 124 from the host device overrides the stored enablement indication 512, and the memory device performs an undelayed refresh operation 126-2 at 806. Thus, the refresh logic 120 can perform, without waiting for the delay period 410, the refresh operation based on the presence of the override indicator 820 or based on an affirmative value of the override indicator 820. If there is no override indicator as determined at 808, then execution of the process proceeds to operation 810.

At 810, the memory device determines the delay period 410 (e.g., tREFL) based on the currently stored refresh latency indication 122. Alternatively, the memory device refers to a previously computed delay period 410 or obtains the currently stored refresh latency indication 122 to perform a comparison. If the refresh latency indication 122 is zero (e.g., if REFLn=0), then the memory device performs an undelayed refresh operation 126-2 at 806. On the other hand, if the refresh latency indication 122 is not zero (e.g., if REFLn>0), then the memory device performs a delayed refresh operation 126-1 at 812. However, a memory device may process parameters or variables (e.g., an enablement indication 512, a refresh command 124 (including a refresh command with an override indicator 124*), or a refresh latency indication 122) in different manners to determine whether to perform an undelayed refresh operation 126-2 or a delayed refresh operation 126-1.

FIG. 9 illustrates a flow diagram 900, which includes operations 902 and 904, for implementing aspects of refresh latency indication for refresh operations for a host device. In aspects, operations of the method 900 can be implemented by refresh logic 118 in conjunction with an interface 506 of a host device 104 as described with reference to FIGS. 1 to 7.

At block 902, a refresh latency indication is generated for a rank of multiple ranks of a memory device. For example, a host device 104 can generate a refresh latency indication 122 for a rank 308 of multiple ranks 308-1 to 308-R of a memory device 108. For instance, a memory controller 114 may generate the refresh latency indication 122 for each die 304 of the rank 308 to be different from the refresh latency indications 122 of memory dies of other rank(s) of the multiple ranks 308-1 to 308-R of the memory device 108. The different memory ranks may be assigned different latencies such that current spikes at the memory device are less additive across multiple ranks when a single refresh command is sent to the multiple ranks.

At block 904, a program-indication command that provides the refresh latency indication is transmitted from an interface to the memory device, with the refresh latency indication effective to cause at least one memory die of the rank of the multiple ranks to delay performance of a refresh operation by a delay period that is based on the refresh latency indication. For example, the host device 104 can transmit, from an interface 506 to the memory device 108, a program-indication command 502 that provides the refresh latency indication 122. The refresh latency indication 122 is effective to cause at least one memory die 304 of the rank 308 of the multiple ranks 308-1 to 308-R to delay performance of a refresh operation 126 by a delay period 410 that is based on the refresh latency indication 122. In some cases, the memory controller 114 may provide the refresh latency indication 122 to the memory device 108 by including the refresh latency indication 122 in the program-indication command 502. Additionally or alternatively, the memory controller 114 may provide the refresh latency indication 122 in a separate but related command, using a reference or pointer to a value, some combination thereof, and so forth.

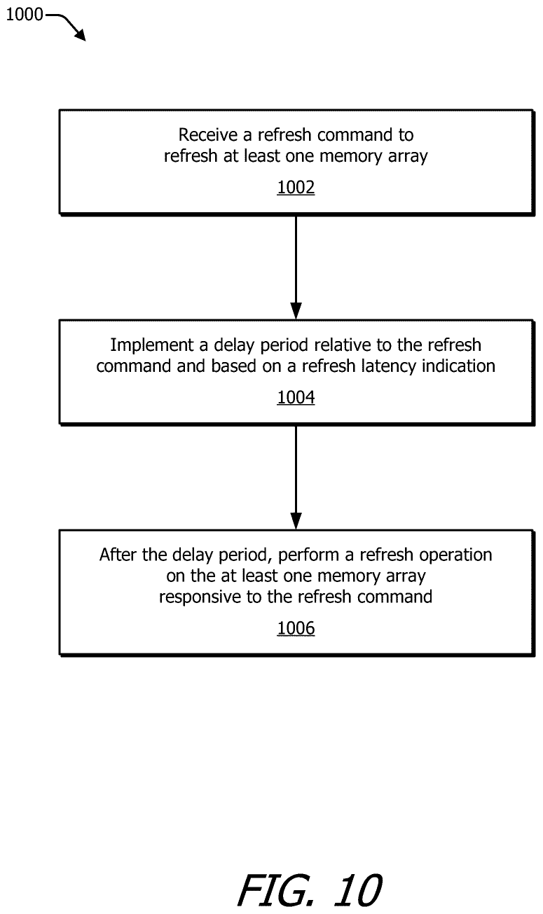

FIG. 10 illustrates a flow diagram 1000, which includes operations 1002-1006, for implementing aspects of refresh latency indication for refresh operations for a memory device. In aspects, operations of the method 1000 can be implemented by refresh logic 120 in conjunction with an interface 206 of a memory device 108 as described with reference to FIGS. 1 to 7.

At block 1002, a refresh command to refresh at least one memory array is received. For example, a memory device 108 can receive a refresh command 124 to refresh at least one memory array 204. For instance, refresh logic 120 may receive the refresh command 124 from a host device 104 via an interconnect 106 using an interface 206. The refresh command 124 may include an override indicator 820 with a negative value or an affirmative value to realize a refresh command with an override indicator 124*.

At block 1004, a delay period is implemented relative to the refresh command and based on the refresh latency indication. For example, the refresh logic 120 can implement a delay period 410 relative to the refresh command 124 and based on the refresh latency indication 122. To do so, the refresh logic 120 may start a timer or otherwise track elapsed time (e.g., a countdown or count-up of clock cycle occurrences) to determine an end of the delay period 410, which period can start responsive to a decoding of the refresh command 124. In some cases, the delay period 410 may be computed using a numerical value of the refresh latency indication 122. Example computational approaches are described above with reference to Tables 1 and 2, but other approaches may be employed instead.

At block 1006, after the delay period, a refresh operation is performed on the at least one memory array responsive to the refresh command. For example, after the delay period 410, the refresh logic 120 can perform a refresh operation 126 on the at least one memory array 204 responsive to the refresh command 124. Here, assuming that the refresh latency mechanism is enabled and that the refresh latency indication 122 is nonzero, after waiting for the expiration of the delay period 410, the refresh logic 120 may initiate a delayed refresh operation 126-1. As described herein, the delay period 410 may differ based on the type of refresh operation commanded to be performed (e.g., auto-refresh operation or self-refresh operation), on a quantity of banks being refreshed by the command (e.g., a single bank or all banks), and so forth.

For the figures and operations described above, the orders in which the operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIGS. 1 to 7, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of refresh latency indication for refresh operations are described:

Example 1: An apparatus comprising:
a memory device comprising:
   at least one memory array;
   at least one memory storage unit configured to store a refresh latency indication; and
   refresh logic coupled to the at least one memory array and the at least one memory storage unit, the refresh logic configured to:
      receive a refresh command to refresh the at least one memory array;
      implement a delay period relative to the refresh command and based on the refresh latency indication; and
      after the delay period, perform a refresh operation on the at least one memory array responsive to the refresh command.

Example 2: The apparatus of example 1, or any other example(s) described herein, wherein:
the refresh latency indication comprises a numerical value; and
the refresh logic is configured to determine the delay period based on the numerical value and a quantity of clock cycles.

Example 3: The apparatus of example 1, or any other example(s) described herein, wherein:
the refresh latency indication comprises a numerical value; and
the refresh logic is configured to determine the delay period based on the numerical value and a length of a clock cycle.

Example 4: The apparatus of example 1, or any other example(s) described herein, wherein the at least one memory storage unit comprises at least one fuse.

Example 5: The apparatus of example 1, or any other example(s) described herein, wherein the at least one memory storage unit comprises at least one register.

Example 6: The apparatus of example 1, or any other example(s) described herein, wherein:
the at least one memory storage unit is configured to store an enablement indication that corresponds to the refresh latency indication.

Example 7: The apparatus of example 6, or any other example(s) described herein, wherein:
the enablement indication comprises an affirmative value; and
the refresh logic is configured to implement the delay period relative to the refresh command, based on the refresh latency indication, and based on the affirmative value of the enablement indication.

Example 8: The apparatus of example 6, or any other example(s) described herein, wherein:
the enablement indication comprises a negative value; and
the refresh logic is configured to:
   receive another refresh command to refresh the at least one memory array while the enablement indication comprises the negative value; and
   perform, without waiting for the delay period, another refresh operation on the at least one memory array responsive to the other refresh command and based on the negative value of the enablement indication.

Example 9: The apparatus of example 6, or any other example(s) described herein, wherein:
the enablement indication comprises an affirmative value; and
the refresh logic is configured to:
   receive another refresh command to refresh the at least one memory array while the enablement indication comprises the affirmative value, the other refresh command including an override indicator; and
   perform, without waiting for the delay period, another refresh operation on the at least one memory array responsive to the other refresh command and based on the override indicator.

Example 10: The apparatus of example 1, or any other example(s) described herein, wherein:
the refresh command comprises a self-refresh entry command.

Example 11: The apparatus of example 10, or any other example(s) described herein, wherein:
the refresh operation comprises a self-refresh operation; and
the refresh logic is configured to, after the delay period:
   enter a self-refresh mode based on the self-refresh entry command; and
   perform the self-refresh operation on the at least one memory array responsive to the self-refresh entry command.

Example 12: The apparatus of example 1, or any other example(s) described herein, wherein:
the refresh command comprises an auto-refresh command.

Example 13: The apparatus of example 12, or any other example(s) described herein, wherein:
the refresh operation comprises an auto-refresh operation; and
the refresh logic is configured to perform, after the delay period, the auto-refresh operation on the at least one memory array responsive to the auto-refresh command.

Example 14: The apparatus of example 12, or any other example(s) described herein, wherein the auto-refresh command comprises at least one of:
an all-bank refresh command (REFab);
a same-bank refresh command (REFsb);
a dual-bank refresh command (REFdb); or
a per-bank refresh command (REFpb).

Example 15: The apparatus of example 1, or any other example(s) described herein, wherein the refresh logic is configured to:
receive a program-indication command to program the refresh latency indication; and
store the refresh latency indication in the at least one memory storage unit based on the program-indication command.

Example 16: The apparatus of example 15, or any other example(s) described herein, wherein:
the memory device comprises at least one interface configured to be coupled to a host device;
the refresh logic is coupled to the at least one interface; and
the refresh logic is configured to:
   receive the refresh command from the host device via the at least one interface; and
   receive the program-indication command from the host device via the at least one interface.

Example 17: The apparatus of example 15, or any other example(s) described herein, wherein:
the at least one memory storage unit comprises at least one mode register;
the program-indication command comprises a mode register write command; and
the refresh logic is configured to store the refresh latency indication in the at least one memory storage unit based on the program-indication command by writing the refresh latency indication in the at least one mode register based on the mode register write command.

Example 18: The apparatus of example 15, or any other example(s) described herein, wherein:
the at least one memory storage unit comprises at least one fuse;
the program-indication command comprises a fuse-blowing command; and
the refresh logic is configured to store the refresh latency indication in the at least one memory storage unit based on the program-indication command by blowing one or more fuses such that the at least one fuse is representative of the refresh latency indication based on the fuse-blowing command.

Example 19: The apparatus of example 18, or any other example(s) described herein, wherein the refresh logic is configured to:
receive the program-indication command from a testing device; and
operate during a test mode of the memory device to store the refresh latency indication by blowing the one or more fuses.

Example 20: A method for a memory device, the method comprising:
receiving a refresh command to refresh at least one memory array of the memory device;
implementing a delay period relative to the refresh command and based on a refresh latency indication; and
performing a refresh operation on the at least one memory array after the delay period and responsive to the refresh command.

Example 21: The method of example 20, or any other example(s) described herein, further comprising:
using the refresh latency indication to determine the delay period;
decoding the refresh command; and
starting the delay period relative to the decoding of the refresh command.

Example 22: An apparatus comprising:
a host device comprising:
   an interface configured to be coupled to a memory device comprising multiple ranks; and
   refresh logic coupled to the interface, the refresh logic configured to:
      generate a refresh latency indication for a rank of the multiple ranks; and
      transmit, from the interface to the memory device, a program-indication command that provides the refresh latency indication, the refresh latency indication effective to cause at least one memory die of the rank of the multiple ranks to delay performance of a refresh operation by a delay period that is based on the refresh latency indication.

Example 23: The apparatus of example 22, or any other example(s) described herein, wherein the refresh logic is configured to:
generate another refresh latency indication for another rank of the multiple ranks; and
transmit, from the interface to the memory device, another program-indication command that provides the other refresh latency indication, the other refresh latency indication effective to cause at least one memory die of the other rank of the multiple ranks to delay performance of a refresh operation by another delay period that is based on the other refresh latency indication, the other refresh latency indication different from the refresh latency indication.

Example 24: The apparatus of example 22, or any other example(s) described herein, wherein the refresh logic is configured to:
transmit, from the interface to the memory device, a refresh command; and
access the memory device in accordance with at least one unrestricted-access period that is shifted responsive to the refresh command and based on the delay period.

Example 25: The apparatus of example 22, or any other example(s) described herein, wherein the refresh logic is configured to:
transmit, from the interface to the memory device, a program-indication command that provides an enablement indication, the enablement indication effective to enable or disable a refresh latency mechanism at the memory device.

Example 26: The apparatus of example 22, or any other example(s) described herein, wherein the refresh logic is configured to:
transmit, from the interface to the memory device, a refresh command with an override indicator; and
access the memory device in accordance with at least one unrestricted-access period that is unshifted responsive to the refresh command and based on the override indicator.

Example 27: The apparatus of example 1, or any other example(s) described herein, wherein:
the memory device comprises multiple ranks; and
the memory device is configured to:
   receive, from a host device, a program-indication command that provides the refresh latency indication for a rank of the multiple ranks; and
   cause at least one die of the rank of the multiple ranks to delay the refresh operation by the delay period that is based on the refresh latency indication.

Example 28: The apparatus of example 27, or any other example(s) described herein, wherein the memory device is configured to:
store the refresh latency indication at the at least one die of the rank.

Example 29: The apparatus of example 27, or any other example(s) described herein, wherein the memory device is configured to:
cause each die of the rank of the multiple ranks to delay the refresh operation by the delay period that is based on the refresh latency indication.

Example 30: The apparatus of example 1, or any other example(s) described herein, wherein:
the memory device comprises multiple ranks;
the at least one memory storage unit comprises multiple memory storage units configured to store multiple refresh latency indications, each respective memory storge unit of the multiple memory storage units configured to store a respective refresh latency indication of the multiple refresh latency indications corresponding to a respective rank of the multiple ranks; and
at least two of the multiple refresh latency indications for different ranks have different values.

Example 31: The apparatus of example 30, or any other example(s) described herein, wherein:
each respective refresh latency indication that corresponds to a respective rank is different from each other refresh latency indication corresponding to a different rank.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of implementing refresh latency indication for refresh operations have been described in language specific to certain features and/or methods, the subject of the appended claims is not necessarily limited to the specific features or methods described. Rather, the specific features and methods are disclosed as a variety of example implementations for refresh latency indication for refresh operations.

What is claimed is:

1. An apparatus comprising:
a memory device comprising:
at least one memory array;
at least one memory storage unit configured to store a refresh latency indication; and
refresh logic coupled to the at least one memory array and the at least one memory storage unit, the refresh logic configured to:
receive a refresh command to refresh the at least one memory array;
implement a delay period relative to the refresh command and based on the refresh latency indication; and
after the delay period, perform a refresh operation on the at least one memory array responsive to the refresh command.

2. The apparatus of claim 1, wherein:
the refresh latency indication comprises a numerical value; and
the refresh logic is configured to determine the delay period based on the numerical value and a quantity of clock cycles.

3. The apparatus of claim 1, wherein:
the refresh latency indication comprises a numerical value; and
the refresh logic is configured to determine the delay period based on the numerical value and a length of a clock cycle.

4. The apparatus of claim 1, wherein:
the at least one memory storage unit is configured to store an enablement indication that corresponds to the refresh latency indication.

5. The apparatus of claim 4, wherein:
the enablement indication comprises an affirmative value; and
the refresh logic is configured to implement the delay period relative to the refresh command, based on the refresh latency indication, and based on the affirmative value of the enablement indication.

6. The apparatus of claim 4, wherein:
the enablement indication comprises a negative value; and
the refresh logic is configured to:
receive another refresh command to refresh the at least one memory array while the enablement indication comprises the negative value; and
perform, without waiting for the delay period, another refresh operation on the at least one memory array responsive to the other refresh command and based on the negative value of the enablement indication.

7. The apparatus of claim 4, wherein:
the enablement indication comprises an affirmative value; and
the refresh logic is configured to:
receive another refresh command to refresh the at least one memory array while the enablement indication comprises the affirmative value, the other refresh command including an override indicator; and
perform, without waiting for the delay period, another refresh operation on the at least one memory array responsive to the other refresh command and based on the override indicator.

8. The apparatus of claim 1, wherein:
the refresh command comprises a self-refresh entry command.

9. The apparatus of claim 8, wherein:
the refresh operation comprises a self-refresh operation; and
the refresh logic is configured to, after the delay period:
enter a self-refresh mode based on the self-refresh entry command; and
perform the self-refresh operation on the at least one memory array responsive to the self-refresh entry command.

10. The apparatus of claim 1, wherein:
the refresh command comprises an auto-refresh command.

11. The apparatus of claim 10, wherein:
the refresh operation comprises an auto-refresh operation; and
the refresh logic is configured to perform, after the delay period, the auto-refresh operation on the at least one memory array responsive to the auto-refresh command.

12. The apparatus of claim 1, wherein the refresh logic is configured to:
receive a program-indication command to program the refresh latency indication; and
store the refresh latency indication in the at least one memory storage unit based on the program-indication command.

13. The apparatus of claim 12, wherein:
the at least one memory storage unit comprises at least one mode register;
the program-indication command comprises a mode register write command; and
the refresh logic is configured to store the refresh latency indication in the at least one memory storage unit based on the program-indication command by writing the refresh latency indication in the at least one mode register based on the mode register write command.

14. The apparatus of claim 12, wherein:
the at least one memory storage unit comprises at least one fuse;
the program-indication command comprises a fuse-blowing command; and
the refresh logic is configured to store the refresh latency indication in the at least one memory storage unit based on the program-indication command by blowing one or more fuses such that the at least one fuse is representative of the refresh latency indication based on the fuse-blowing command.

15. A method for a memory device, the method comprising:
receiving a refresh command to refresh at least one memory array of the memory device;
implementing a delay period relative to the refresh command and based on a refresh latency indication; and
performing a refresh operation on the at least one memory array after the delay period and responsive to the refresh command.

16. The method of claim 15, further comprising:
using the refresh latency indication to determine the delay period;
decoding the refresh command; and
starting the delay period relative to the decoding of the refresh command.

17. An apparatus comprising:
a host device comprising:
an interface configured to be coupled to a memory device comprising multiple ranks; and
refresh logic coupled to the interface, the refresh logic configured to:
generate a refresh latency indication for a rank of the multiple ranks; and
transmit, from the interface to the memory device, a program-indication command that provides the refresh latency indication, the refresh latency indication effective to cause at least one memory die of the rank of the multiple ranks to delay performance of a refresh operation by a delay period that is based on the refresh latency indication.

18. The apparatus of claim 17, wherein the refresh logic is configured to:
transmit, from the interface to the memory device, a refresh command; and
access the memory device in accordance with at least one unrestricted-access period that is shifted responsive to the refresh command and based on the delay period.

19. The apparatus of claim 17, wherein the refresh logic is configured to:
transmit, from the interface to the memory device, a program-indication command that provides an enablement indication, the enablement indication effective to enable or disable a refresh latency mechanism at the memory device.

20. The apparatus of claim 17, wherein the refresh logic is configured to:
transmit, from the interface to the memory device, a refresh command with an override indicator; and
access the memory device in accordance with at least one unrestricted-access period that is unshifted responsive to the refresh command and based on the override indicator.
